(19) United States
(12) Patent Application Publication
(10) Pub. No.: US 2025/0153208 A1
(43) Pub. Date: May 15, 2025

(54) SUBSTRATE PROCESSING APPARATUS AND SUBSTRATE PROCESSING METHOD

(71) Applicant: SEMES CO., LTD., Cheonan-si (KR)

(72) Inventors: Sang Hu HAN, Cheonan-si (KR); Young Joon HAN, Cheonan-si (KR); Cheol Hwan JEONG, Pyeongtaek-si (KR); Ju Ha WOO, Anseong-si (KR)

(73) Assignee: SEMES CO., LTD., Cheonan-si (KR)

(21) Appl. No.: 18/935,860

(22) Filed: Nov. 4, 2024

(30) Foreign Application Priority Data
Nov. 15, 2023 (KR) 10-2023-0158065

(51) Int. Cl. B05B 12/08; B08B 3/02

(52) U.S. Cl. CPC B05B 12/085; B08B 3/02

(57) ABSTRACT

Disclosed is an apparatus for processing a substrate, the apparatus including: a cup providing a processing space; a support unit provided in the processing space, and for supporting a substrate; a support unit provided in the processing space, and for supporting a substrate; a liquid supply unit including a nozzle for discharging a liquid to the substrate; a position adjuster coupled to the nozzle and for adjusting a position of the nozzle; and an adjustment unit coupled to the support unit, and for detecting pressure data when the liquid discharged from the nozzle meets the adjustment unit and position information at which the pressure data is generated.

### CROSS-REFERENCE TO RELATED APPLICATIONS

This application claims priority to and the benefit of Korean Patent Application No. 10-2023-0158065 filed in the Korean Intellectual Property Office on Nov. 15, 2023, the entire contents of which are incorporated herein by reference.

### TECHNICAL FIELD

The present invention relates to a substrate processing apparatus and a substrate processing method that process a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

The etching processes typically utilize a dry etching process and a wet etching process, and there is a substrate processing apparatus that etches the edge of the substrate by using wet etching. The substrate processing apparatus is often referred to as a bevel etcher or a bevel etching device.

These bevel etching device often utilize dry etching using plasma, but there is also a wet bevel etching device that utilizes wet etching.

The wet bevel etching device positions a nozzle at the edge of the substrate and then discharges a treatment solution onto the edge of the rotating substrate to etch the edge of the substrate.

In this case, the wet bevel etching device requires the discharge position of the treatment solution to be precisely at the targeted point to accurately etch the edge of the substrate. In order to accurately determine the discharge position, the discharge position is either adjusted by visually checking the actual discharge point or by discharging the liquid on a test plate with a deposition film that reacts with the liquid.

However, this method of determining the discharge position by visual inspection or using a test plate has the problem that it is difficult to accurately determine the discharge point, and the results are different depending on the measurement method and the skill of the measurer.

### SUMMARY OF THE INVENTION

The present invention has been made in an effort to provide a substrate processing apparatus and a substrate processing method that can quantitatively determine a discharge position of a nozzle and adjust a position of the nozzle without having to visually determine the discharge position of the nozzle or utilize a test plate.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a cup providing a processing space; a support unit provided in the processing space, and for supporting a substrate; a support unit provided in the processing space, and for supporting a substrate; a liquid supply unit including a nozzle for discharging a liquid to the substrate; a position adjuster coupled to the nozzle and for adjusting a position of the nozzle; and an adjustment unit coupled to the support unit, and for detecting pressure data when the liquid discharged from the nozzle meets the adjustment unit and position information at which the pressure data is generated

According to the exemplary embodiment, the adjustment unit may include: a base part seated on the support unit in place of the substrate; a sensing part coupled to a top surface of the base part and including a plurality of pressure detecting elements that generates pressure data when receiving a pressure; and a mapping part interworking with the sensing part and mapping position information to pressure data detected by each of the pressure detecting elements configuring the sensing part.

According to the exemplary embodiment, the base part may be formed in a disk shape similar to the substrate.

According to the exemplary embodiment, the sensing part may be formed in a ring shape when viewed from above.

According to the exemplary embodiment, an outer diameter of the sensing part may be formed with an outer diameter smaller than an outer diameter of the base part, and the outer diameter of the sensing part may be spaced apart from the outer diameter of the base part by a predetermined distance.

According to the exemplary embodiment, the mapping part may calculate a data center value of the mapped pressure data.

According to the exemplary embodiment, the mapping part may filter the pressure data so that only pressure data of a predetermined value or greater is mapped among the pressure data.

According to the exemplary embodiment, the position information of each of the filtered mapping data may be arithmetically averaged and calculated as a data center value.

According to the exemplary embodiment, the adjustment unit may further include a display part which interworks with the mapping part to receive pressure data and position information matched with the pressure data, generates mapping data based on the pressure data and the position information input from the mapping part, and displays the input pressure data and position information as the mapping data.

According to the exemplary embodiment, the adjustment unit may further include a position control part which interworks with the position adjuster, and transmits a position adjustment signal to the position adjuster to adjust the position of the nozzle.

According to the exemplary embodiment, the nozzle may include a plurality of nozzles, at least one of the plurality of nozzles may be a nozzle for spraying a treatment solution to process the substrate, and at least another of the plurality of nozzles may be a nozzle for spraying a cleaning liquid to clean the substrate, and the adjustment unit may detect the pressure data and the position information for the plurality of nozzles.

According to the exemplary embodiment, the apparatus may further include a scattering preventing guide disposed in an upper space of the support unit, and formed with a nozzle insertion groove into which the nozzle is inserted and which is formed from a lateral surface toward the center.

Another exemplary embodiment of the present invention provides a method of processing a substrate, the method including: an adjustment unit insertion operation of seating an adjustment unit on a support unit located inside a processing space of a housing; an adjustment unit adjustment operation of moving, by a centering unit, the adjustment unit seated on the support unit to align a center of the adjustment unit with a center of the support unit; a liquid spraying operation of discharging a liquid from a nozzle to the adjustment unit; a spray position detection operation of detecting, by the adjustment unit, pressure data generated when the liquid discharged from the nozzle contacts the adjustment unit and position information at which the liquid contacts the adjustment unit; a spray position adjustment operation of outputting the pressure data and the position information detected by the adjustment unit as mapping data, and adjusting a position of the nozzle by a travel distance from the output mapping data to a target discharge position; an adjustment unit discharge operation of discharging the adjustment unit to the outside of the processing space of the housing; and a substrate processing operation of loading a substrate into the support unit, and processing the substrate by spraying a treatment solution from the nozzle in a state where the loaded substrate is rotated.

According to the exemplary embodiment, the spray position detection operation may include detecting the pressure data within a region in a ring shape as viewed from above when detecting the pressure data.

According to the exemplary embodiment, the spray position detection operation may include displaying the mapping data.

According to the exemplary embodiment, the spray position detection operation may include calculating a data center value of the mapping data.

According to the exemplary embodiment, the substrate processing operation may include adjusting the position of the nozzle by a value for a difference between the data center value of the mapping data and the target discharge position in a bevel region of the substrate.

According to the exemplary embodiment, the spray position detection operation may include calculating the data center value in a state where pressure data for pressures of a predetermined value or lower of the mapping data is filtered.

According to the exemplary embodiment, the substrate processing operation may include discharging the treatment solution and bevel-etching an edge of the substrate.

Still another exemplary embodiment of the present invention provides an apparatus for processing a substrate, the apparatus including: a cup providing a processing space; a support unit provided in the processing space, and for supporting a substrate; a liquid supply unit including a nozzle for discharging a liquid onto the substrate; a position adjuster coupled to the nozzle and for adjusting a position of the nozzle; and an adjustment unit seated on the support unit and for detecting pressure data generated when the liquid discharged from the nozzle contacts the adjustment unit and position information at which the pressure data is generated, in which the adjustment unit includes: a base part seated on the support unit in place of the substrate and formed in a shape of a disk; a sensing part coupled to an upper surface of the base part, and including a plurality of pressure detecting elements that generate pressure data when receiving a pressure, and formed in a ring shape, and having an outer diameter smaller than an outer diameter of the base part; a mapping part interworking with the sensing part and mapping position information to the pressure data detected by each of the pressure detecting elements configuring the sensing part; a display part which interworks with the mapping part to receive pressure data and position information matched with the pressure data, generates mapping data based on the pressure data and the position information input from the mapping part, and displays the input pressure data and the position information as the mapping data; and a position control part which interworks with the position adjuster and transmits a position adjustment signal to the position adjuster to adjust the position of the nozzle.

The present invention has the effect of quantitatively determining a discharge position of a nozzle and adjusting a position of the nozzle without having to visually determine the discharge position of the nozzle or utilize a test plate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a cross-sectional view of a substrate processing apparatus according to an exemplary embodiment of the present invention.

FIG. 2 is a perspective view of the substrate processing apparatus illustrated in FIG. 1 with a nozzle and a jig removed.

FIG. 3 is a top plan view of a centering unit illustrated in FIG. 2.

FIG. 4 is a perspective view of the substrate processing apparatus illustrated in FIG. 1 with the nozzle and the jig removed.

FIG. 5 is an enlarged view of a sensing part illustrated in FIG. 4.

FIG. 6 is a graphical representation of mapping data recorded on a mapping part illustrated in FIG. 4.

FIG. 7 is a flowchart of a substrate processing method according to an exemplary embodiment of the present invention.

FIG. 8 is a schematic cross-sectional view of raised and lowered states of a raising and lowering cover and an outer cup illustrated in FIG. 1.

FIG. 9 is a cross-sectional view of the substrate in a state of liquid treatment.

FIG. 10 is an enlarged partial cross-sectional view of a first nozzle illustrated in FIG. 9 and its surroundings.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In this exemplary embodiment, a wafer is described as an example of an object to be processed. However, the technical spirit of the present invention may be applied to devices used for other types of substrate treatment, in addition to wafers.

Hereinafter, exemplary embodiments of the present invention will be described with reference to the accompanying drawings.

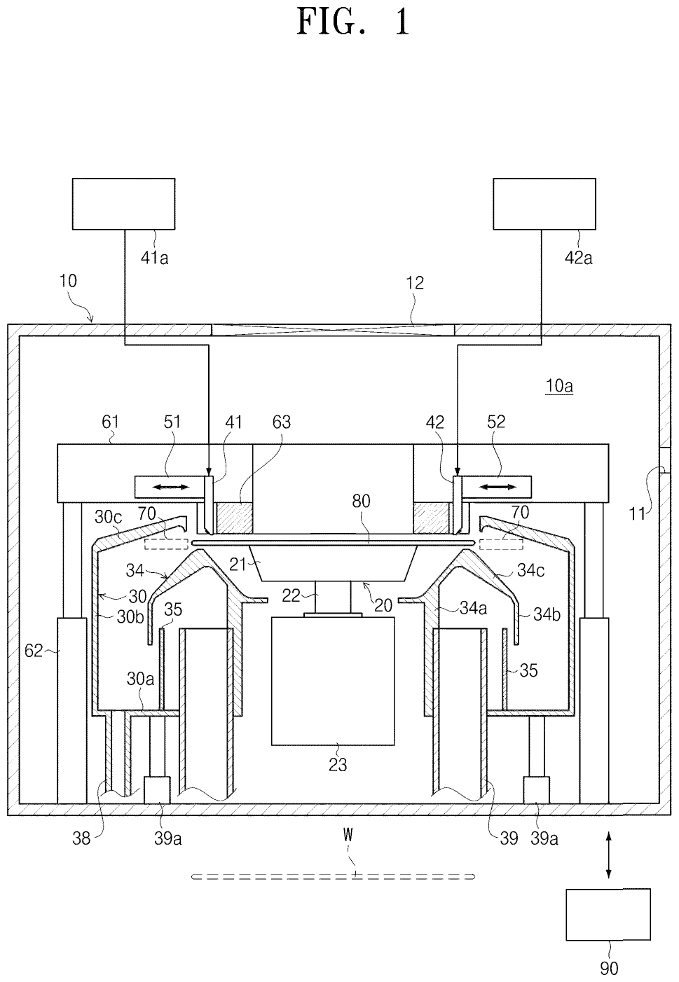

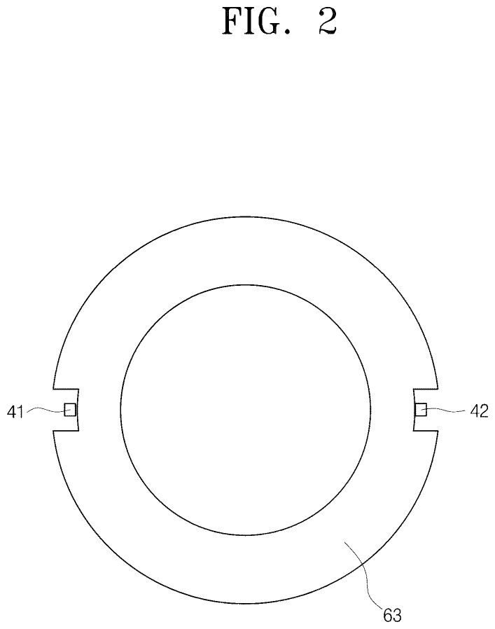

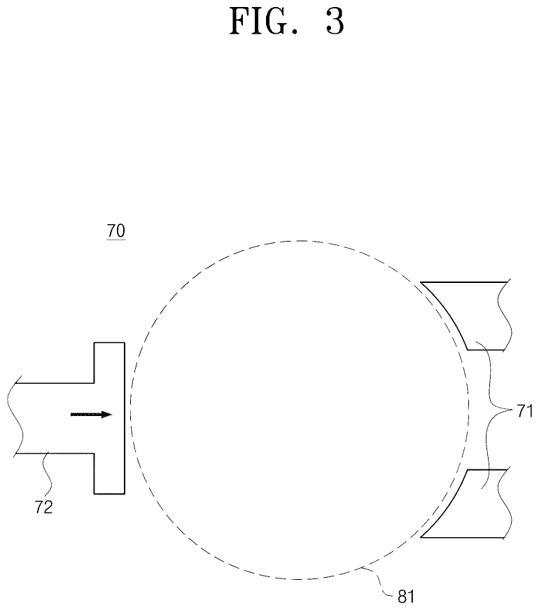

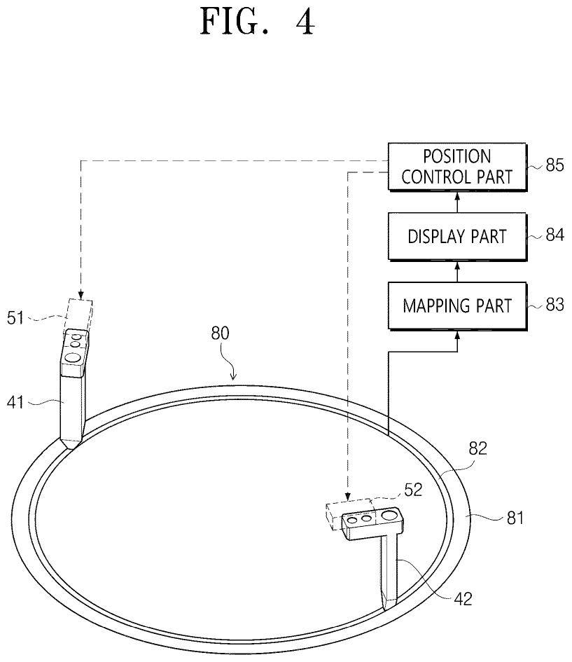

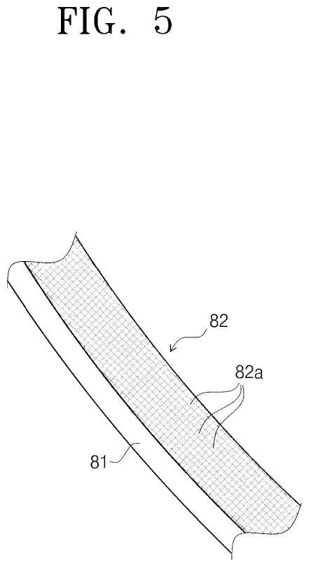

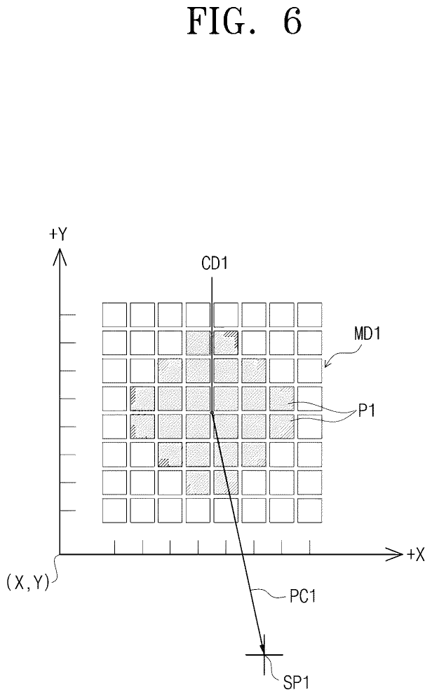

FIG. 1 is a cross-sectional view of a substrate processing apparatus according to an exemplary embodiment of the present invention. FIG. 2 is a top plan view of a scattering preventing guide and a nozzle illustrated in FIG. 1. FIG. 3 is a top plan view of a centering unit illustrated in FIG. 2. FIG. 4 is a perspective view of the substrate processing apparatus illustrated in FIG. 1 with the nozzle and the jig removed. FIG. 5 is an enlarged view of a sensing part illustrated in FIG. 4. FIG. 6 is a graphical representation of mapping data recorded on a mapping part illustrated in FIG. 4.

As illustrated in FIGS. 1 to 6, a substrate processing apparatus according to an exemplary embodiment of the present invention may include a housing 10, a support unit 20, an outer cup 30, a liquid supply unit 40, positioning adjusters 51 and 52, a raising and lowering unit 60, a centering unit 70, an adjustment unit 80, and a process controller 90.

The housing 10 is provided in a rectangular cylindrical shape having an inner space. An opening 10 is formed in one side of the housing 11. The opening 11 functions as a passageway through which the substrate W enters and exits. A door (not illustrated) is installed in the opening 11, which opens and closes the opening. An inner space of the housing 10 is provided with the outer cup 30. The outer cup 30 has a processing space 10a with an open top. On the top wall of the housing 10, a fan filter unit 12 is disposed to supply a downward airflow to the inner space. The fan filter unit 12 includes a fan to introduce air from the outside into the inner space and a filter to filter the outside air.

The support unit 20 supports the substrate W within the processing space 10a of the outer cup 30. The support unit 20 includes a support plate 21, a rotation shaft 22, and a driver 23. The support plate 21 is provided with a circular top surface. The support plate 422 has a diameter smaller than the substrate W. The support plate 21 is provided to support the substrate W under vacuum pressure. The rotation shaft 22 is coupled to the center of the bottom surface of the support plate 21, and the rotation shaft 22 is provided with the driver 1460 that provides rotational force to the rotation shaft 22. The driver 23 may be a motor. Further, a lifting driver (not illustrated) may be provided for adjusting the relative height of the support plate 21 and the outer cup 30.

The outer cup 30 has a bottom wall 30a, a lateral wall 30b, and a top wall 30c. The inner portion of the outer cup 30 is provided as the inner space described above. The inner space includes a processing space 10a at the top and an exhaust space at the bottom.

The bottom wall 30a is provided in a circular shape and has an opening in the center. The lateral wall 30b extends upwardly from an outer end of the bottom wall 30a. The lateral wall 30b is provided in a ring shape and is provided perpendicular to the bottom wall 30a. In one example, the lateral wall 30b extends to the same height as the top surface of the support plate 21, or extends to a height slightly lower than the top surface of the support plate 21. The top wall 30c has a ring shape and has an opening in the center. The upper wall 30c is provided to slope upwardly from the top end of the lateral wall 30b towards the center axis of the outer cup 30.

The guide cup 34 is located on the inner side of the outer cup 30. The guide cup 34 has an inner wall 34a, an outer wall 34b, and a top wall 34c. The inner wall 34a has a through-hole that is perforated in the vertical direction. The inner wall 34a is disposed to surround the driver 23. The inner wall 34a minimizes exposure of the driver 23 to the airflow in the processing space 10a. The rotation shaft 22 and/or the driver 23 of the support unit 20 extend in an upward and downward direction through the through-hole. The outer wall 34b is spaced apart from the inner wall 34a and is arranged to wrap around the inner wall 34a. The outer wall 34b is spaced apart from the lateral wall 30b of the outer cup 30. The inner wall 34a is spaced upwardly from the bottom wall 30a of the outer cup 30. The top wall 34c connects the top end of the outer wall 34b to the top end of the inner wall 34a. The top wall 34c has a ring shape and is disposed to wrap around the support plate 21. In one example, the upper wall 34c has an upwardly convex shape.

The space below the support plate 21 in the processing space 10a may be provided as an exhaust space. In one example, the exhaust space may be defined by the guide cup 34. The space enclosed by the outer wall 34b, the top wall 34c, and the inner wall 34a of the guide cup 34 and/or the space below the foregoing space may be provided as the exhaust space.

The outer cup 30 may be provided with a gas-liquid separation plate 35. The gas-liquid separation plate 35 may be provided to extend upwardly from the bottom wall 30a of the outer cup 30. The gas-liquid separation plate 35 may be provided in a ring shape. The gas-liquid separation plate 35 may be positioned between the lateral wall 30b of the outer cup 30 and the outer wall 34b of the guide cup 34 when viewed from above. The top end of the gas-liquid separation plate 35 may be positioned at a lower level than the bottom end of the outer wall 34b of the guide cup 34.

The bottom wall 30a of the outer cup 30 is connected to a discharge outlet pipe 38 for discharging the treatment solution, an exhaust pipe 39, and a driver 39a. The discharge pipe 38 may be connected to the outer cup 30 from the outer side of the gas-liquid separation plate 35. The exhaust pipe 39 may be connected to the outer cup 30 from the inner side of the gas-liquid separation plate 35. The driver 39a may raise and lower the outer cup 30.

The liquid supply unit 40 supplies the treatment solution onto the substrate W.

The liquid supply unit 40 may include a first nozzle 41 and a second nozzle 42.

The first nozzle 41 may be a treatment solution supply nozzle that receives a treatment solution from a treatment solution supply source 41a and discharges the treatment solution. The first nozzle 41 may be located in a space above the sensing part 82 and may dispense the treatment solution to the sensing part 82. In one example, the treatment solution may include hydrofluoric acid.

The second nozzle 42 may be a cleaning solution supply nozzle that receives a cleaning solution from a cleaning solution supply source 42a and discharges the cleaning solution. The second nozzle 42 may be located in a space above the sensing part 82 and may discharge the cleaning solution to the sensing part 82. In one example, the cleaning solution may be pure water.

Meanwhile, the first nozzle 41 and the second nozzle 42 may be formed such that the spray direction of the outlet ports are downwardly directed toward the upper surface of a base part 81 but inclined at a predetermined angle in a direction perpendicular to the upper surface of the substrate W. As a result, the liquids discharged from the first nozzle 41 and the second nozzle 42 may be less likely to scatter when the liquids come into contact with the base part 81.

The position adjusters 51 and 52 may include a first position adjuster 51 and a second position adjuster 52.

The first position adjuster 51 may be formed of a driver that drives in-line or in-plane. Here, the driver may be formed of a linear motor or an actuator for positioning. The first position adjuster 51 may be coupled to a portion of a body of the first nozzle 41 to adjust the position of the first nozzle 41. Further, the first position adjuster 51 may adjust the position of the first nozzle 41 automatically or manually. When the first position adjuster 51 automatically adjusts the position of the first nozzle 41, the drive is controlled by a position control part 85 to adjust the position of the first nozzle 41.

The second position adjuster 5 may be formed of a driver that drives in-line or in-plane. The second position adjuster 52 may be coupled to a portion of a body of the second nozzle 42 to adjust the position of the second nozzle 42. Further, the second position adjuster 52 may adjust the position of the second nozzle 41 automatically or manually. When the second position adjuster 51 automatically adjusts the position of the second nozzle 42, the drive is controlled by the position control part 85 to adjust the position of the second nozzle 42.

The raising and lowering unit 60 may include a raising and lowering cover 61, a raising and lowering driver 62, and a scattering preventing guide 63.

The raising and lowering cover 61 is disposed in the upper space of the support unit 20 and the outer cup 30. The raising and lowering cover 61 may provide a region for the first position adjuster 51 and the second position adjuster 52 to be coupled. The raising and lowering cover 61 may form a hollow region 61a near the center for light weight.

The raising and lowering driver is coupled to the raising and lowering cover 61. The raising and lowering driver 62 raises the raising and lowering cover 61 to a first position during upward driving and lowers the raising and lowering cover 61 to a second position during downward driving.

The scattering preventing guide 63 is coupled to the raising and lowering cover 61. The scattering preventing guide 63 may be formed in the shape of a ring when viewed from above. The scattering preventing guide 63 may further be formed with a nozzle insertion groove 43a into which the first nozzle 41 and the second nozzle 42 are inserted. The nozzle insertion groove 43a may be formed to extend from the top toward the bottom. Furthermore, the nozzle insertion groove 43a may be formed in a shape that is recessed from a lateral side of the scattering preventing guide 63 toward a central axis. Accordingly, the nozzle insertion groove 43a prevents the liquid that is scattered back from the base part 81 when the first nozzle 41 and the second nozzle 42 discharge the liquid from splashing toward the center side of the base part 81, thereby preventing detection errors from occurring due to the scattering of the liquid.

The centering unit 70 is disposed within the processing space 10a of the housing 10. The centering unit 70 may include a contact plate 71 and a pressurizing plate 72. The contact plate 71 has an arc-shaped face that is in close contact with one side of the base part 81 and may be formed in plural. The pressurizing plate 72 is disposed opposite the contact plate 71 relative to the center of the base part 81 and pressurizes the base part 81 such that the base part 81 is in close contact with the arc-shaped face of the contact plate 71. The pressurizing plate 72 may further include a pressure sensor or a position sensor in the region that is in close contact with the base part 81 to pressurize the base part 81 to a predetermined pressure or a predetermined position. When the adjustment unit 80 is seated on the support unit 20, the centering unit 70 performs the operation of aligning the center of the adjustment unit 80 with the center of the support unit 20 by moving the contact plate 71 and the pressurizing plate 72, which are disposed in the processing space 10a or the outer side of the housing 10, to the lateral side of the base part 81, and by performing the operation of pressurizing, by the pressurizing plate 72, the base part 81 to the arc-shaped face of the contact plate 71. The driving of the centering unit 70 may be controlled by the process controller 90.

The adjustment unit 80 may include the base part 81, the sensing part 82, a mapping part 83, a display part 84, and a position control part 85.

The base part 81 may be formed in a shape that is schematically similar to the shape of the substrate W. In one example, the base part 81 may be formed in the shape of a disk when viewed from above. The base part 81 may be seated on the support unit 20. Further, the position of the base part 81 may be adjusted by a seating plate of the centering unit 70.

The sensing part 82 is coupled to the upper surface of the base part 81. The sensing part 82 may be formed as a ring-shaped film when viewed from above. The outer diameter of the sensing part 82 is formed to be less than the outer diameter of the base part 81, and the separation distance from the outer diameter to the outer diameter of the base part 81 is formed to be constant. Thus, the sensing part 82 accurately senses the discharge position of the liquid to achieve simple mapping and is configured with a small area to reduce manufacturing costs. The sensing part 82 may be composed of pressure detecting elements 82a that detect pressure, which are integrated in the form of cells. Each of the pressure detecting elements 82a configuring the sensing part 82 may be a capacitive sensor. In this case, the sensing part 82 may map position information (X,Y) to each of the pressure detecting elements 82a, and the mapped position information (X,Y) may be stored in the mapping part 83. The sensing part 82 may output pressure data P1 proportional to the input pressure when each of the pressure detecting elements 82a receives a pressure.

Since the base part 81 and the sensing part 82 are inserted in place of the substrate W, it is not necessary to install separate components or remove pre-installed peripheral components to detect the position of the nozzle.

The mapping part 83 is a computational processing unit having a signal processing function and interworks with the sensing part 82 by wired or wireless communication. The mapping part 83 may map position information (X,Y) for each of the pressure sensing elements 82a configuring the sensing part 82. When the mapping part 83 outputs pressure data P1 from each of the pressure detecting elements 82a of the sensing part 82, the mapping part 83 transmits the position information (X,Y) matched with the output pressure data P1 to the display part 84 and the position control part 85. In addition, the mapping part 83 may calculate a data center value CD1 of the mapped data and transmit the calculated data center value CD1 to the display part 84 and the position control part 85.

The display part 84 receives the pressure data P1 and the position information (X,Y) matched with the pressure data P1 in conjunction with the mapping part 83, generates mapping data MD1 based on the pressure data P1 and the position information (X,Y) input from the mapping part 83, and displays the input pressure data P1 and position information (X,Y) as mapping data MD1. The display part 84 may receive the pressure data P1 and the position information (X,Y) by performing wired or wireless communication with the mapping part 83. Further, the display part 84 may display nozzle position values for the current discharge positions of the first nozzle 41 and the second nozzle 42.

The position control part 85 can adjust the position of the first nozzle 41 and the second nozzle 42 to a target discharge position SP1 by interworking with the first position adjuster 51 and the second position adjuster 52. In this case, the position control part 85 may receive the data center value CD1 of the mapping data MD1 from the mapping part 83 and transmit a position control value PC1 to the first position adjuster 51 and the second position adjuster 52 to move the position of the first nozzle 41 and the second nozzle 42 by a distance from the data center value CD1 to the target discharge position SP1, thereby adjusting the positions of the first nozzle 41 and the second nozzle 42. Here, the position control value PC1 may be a value that the operator directly inputs the mapping data MD1 output to the display part 84 into the position control part 85 by viewing the mapping data MD1. Alternatively, the position control value PC1 may be a value that is automatically input to the position control part 85 from the mapping part 83.

The process controller 90 sequentially controls a substrate processing process. Accordingly, the process controller 90 can control a transfer process of loading and unloading the substrate W. Further, the process controller 90 may control a process of rotating the support unit 20. Further, the process controller 90 may control the etching process and the cleaning process by controlling the liquid supply unit to discharge the liquid.

Hereinafter, the substrate processing method will be described.

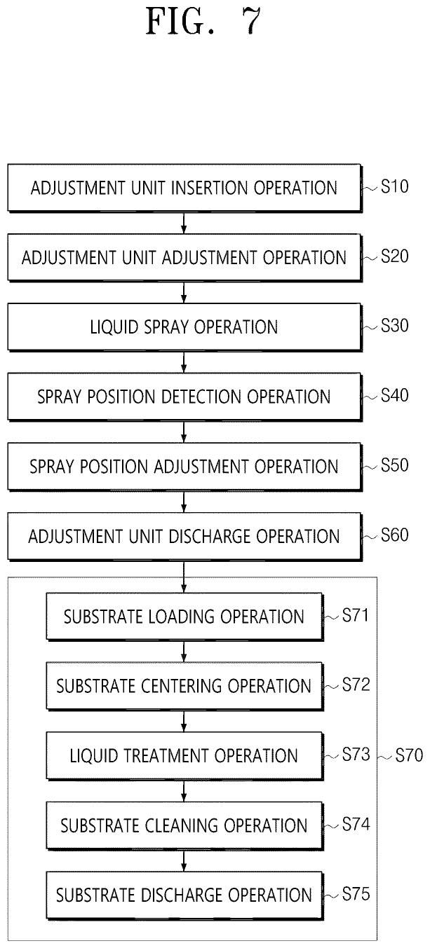

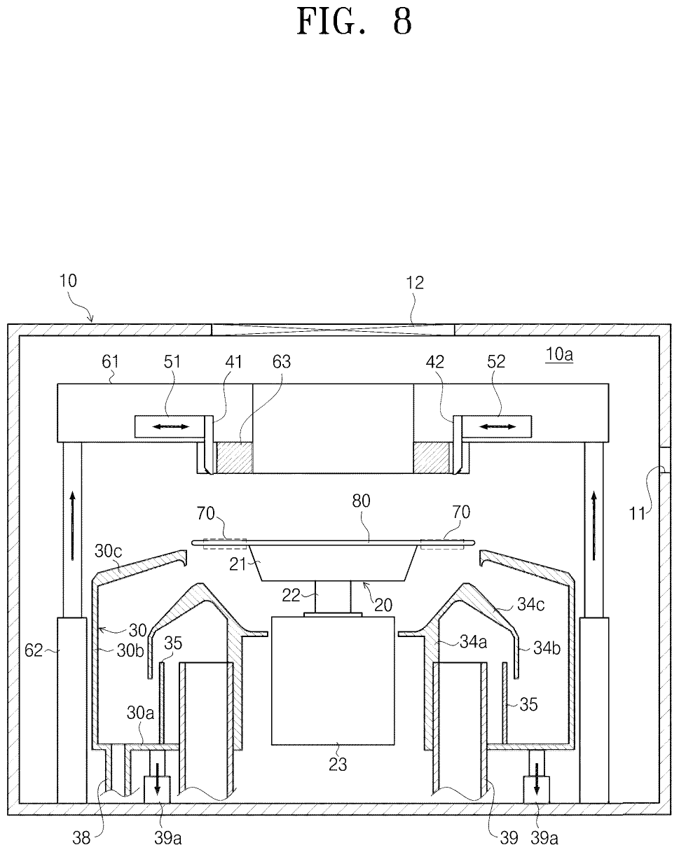

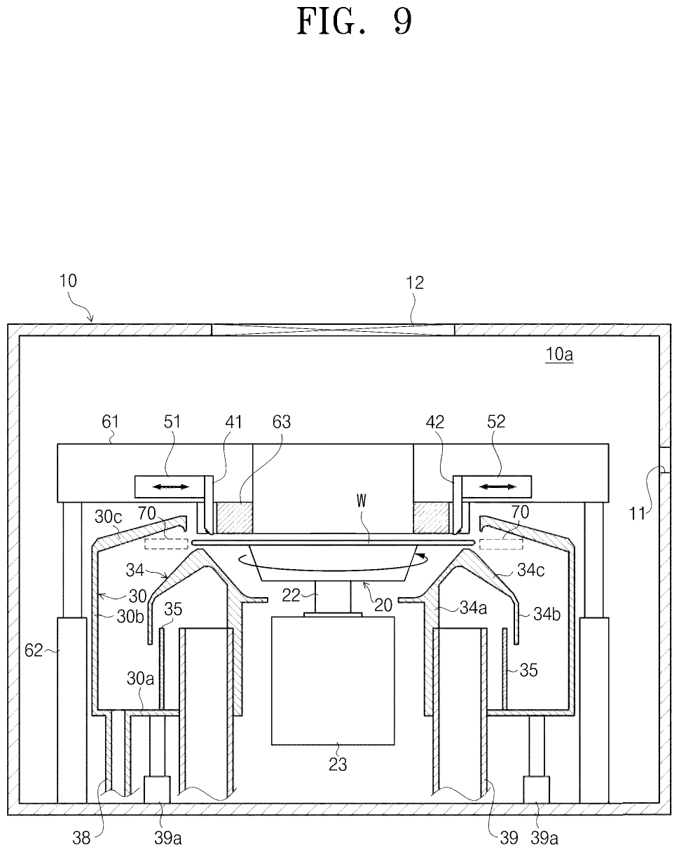

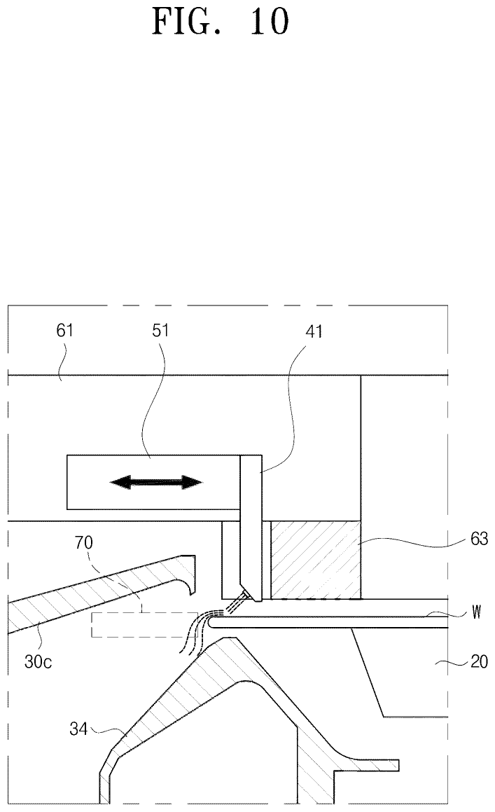

FIG. 7 is a flowchart of a substrate processing method according to an exemplary embodiment of the present invention. FIG. 8 is a schematic cross-sectional view of raised and lowered states of the raising and lowering cover and an outer cup illustrated in FIG. 1. FIG. 9 is a cross-sectional view of the substrate in a state of liquid treatment. FIG. 10 is an enlarged partial cross-sectional view of the first nozzle illustrated in FIG. 9 and its surroundings.

Referring further to FIG. 7, a substrate processing method according to an exemplary embodiment of the present invention includes an adjustment unit insertion operation S10, an adjustment unit adjustment operation S20, a liquid spraying operation S30, a spray position detection operation S40, a spray position adjustment operation S50, an adjustment unit ejection operation S60, and a substrate processing operation S70.

In the adjustment unit insertion operation S10, the adjustment unit 80 is seated on the support unit 20 located inside the processing space 10a of the housing 10. In this case, the adjustment unit 80 may be transferred by a transfer robot (not illustrated).

In the adjustment unit adjustment operation S20, the centering unit 70 as described above moves the adjustment unit 80 seated on the support unit 20 to align the center of the adjustment unit 80 with the center of the support unit 20. In this case, the adjustment unit 80 may be pressed against the contact plate 71 by the pressurizing plate 72, as illustrated in FIG. 3, so that their centers are aligned. Accordingly, the center of the adjustment unit 80 may be aligned with the process center (not illustrated) in the mapping data MD1. In the case of proceeding with the adjustment unit adjustment operation S20, as illustrated in FIG. 8, the raising and lowering cover 61 may be raised upward by the raising and lowering driver 62 and the outer cup 30 may be lowered downward by the driver 39a.

In the liquid spraying operation S30, a liquid is discharged from each of the first nozzle 41 and the second nozzle 42 to the sensing part 82 of the adjustment unit 80. In this case, the first nozzle 41 and the second nozzle 42 may discharge pure water as the liquid.

In the spray position detection operation S40, the sensing part 82 detects the pressure data P1 and the position information (X,Y) of a contact position of the liquid when the liquid discharged from the first nozzle 41 and the second nozzle 42 meets the sensing part 82, and the mapping part 83 transmits the pressure data P1 and the position information (X,Y) to the display part 84 and the position control part 85.

In the spray position adjustment operation S50, the display part 84 may outputs the pressure data P1 and the position information (X,Y) input from the mapping part 83 as mapping data MD1. In this case, an operator can adjust the positions of the first nozzle 41 and the second nozzle 42 by visually checking the mapping data MD1 output on the display part 84 and inputting a position control value PC1 to the position control part 85 by a travel distance to a target discharge position SP1 to adjust the position adjuster. As described above, the pressure data P1 and the position information (X,Y) correspond to a plurality of values distributed over a predetermined region, and in this case, the mapping part 83 may calculate a data center value CD1 of the mapping data MD1 in the case where the pressure data P1 is distributed as the mapping data MD1 over the predetermined region. In this case, the position control part 85 may adjust the positions of the first nozzle 41 and the second nozzle 42 by adjusting each of the first position adjuster 51 and the second position adjuster 52 with the calculated data center value CD1. Referring now to the drawings for a more detailed explanation, as illustrated in FIGS. 4 to 6, the pressure data P1 and the position information X,Y input from the mapping part 83 when the liquid is discharged from the first nozzle 41 to the sensing part 82 are recorded as the mapping data MD1 by the mapping part 83. In this case, the mapping part 83 calculates the data center value CD1 of the data from the mapping data MD1, and transmits the position control value PC1 for the difference between the calculated data center value CD1 and the target discharge position SP1 to the first position adjuster 51 to adjust the position of the first nozzle 41. At this time, the method of calculating the data center value CD1 by the mapping part 83 may be to filter the pressure data P1 so that only the pressure data P1 of a predetermined value or greater is mapped, and then calculate an arithmetic mean of the position information of the filtered mapping data MD1 to calculate a mean coordinate value as the data center value CD1. That is, the discharge position of the nozzle can be detected by detecting the region where the strongest pressure is generated in the region where the liquid is discharged. In the same way, the position of the second nozzle 42 can be adjusted by transmitting the position control value PC1 between the center value of the mapping data MD1 and the target discharge position SP1 to the second position adjuster 52 to adjust the position of the second nozzle 42.

In the adjustment unit ejection operation S60, the adjustment unit 80 is ejected outside the processing space 10a of the housing 10. In this case, the adjustment unit 80 may be transferred to the outside by a transfer robot (not illustrated) or transferred to the outside by manual labor. In the adjustment unit discharge operation S60, as illustrated in FIG. 8, the raising and lowering cover 61 may be driven by the raising and lowering driver 62 to rise to the top.

The substrate processing operation S70 may include a substrate loading operation S71, a substrate centering operation S72, a liquid treatment operation S73, a substrate cleaning operation S74, and a substrate discharge operation S75.

The substrate loading operation S71 is an operation in which the transfer robot (not illustrated) seats the substrate W onto the support unit 20 located inside the processing space 10a.

The substrate centering operation S72 is an operation in which the centering unit 70 moves the substrate W seated on the support unit 20 to align the center of the substrate W with the center of the support unit 20. In this case, the centering operation of the substrate W may be performed in a state in which the raising and lowering cover 61 is raised upwardly by the raising and lowering driver 62 and the outer cup 30 is lowered downwardly by the driver 39a.

The liquid treatment operation S73 is an operation in which the substrate W is processed by supplying a treatment solution from the first nozzle 41 to the edge of the substrate W as illustrated in FIG. 10 while the support unit 20 has rotated the substrate W as illustrated in FIG. 9. In this case, the treatment solution may be a liquid for etching the substrate W, and as described above, the treatment solution may be hydrofluoric acid. In the liquid treatment operation S73, the treatment solution may be discharged to bevel etch the edge of the substrate W.

The substrate cleaning operation S74 is an operation in which the second nozzle 42 supplies a cleaning solution to the edge of the substrate W while the support unit 20 rotates the substrate W. In this case, the cleaning solution may be pure water. After completing the substrate cleaning operation S74, the support unit 20 stops the rotation of the substrate W.

The substrate discharge operation S75 is an operation in which the transfer robot discharges the cleaned substrate W to the outside of the housing 10. In this case, the substrate W discharged from the outside of the housing 10 may be placed in a poop (not illustrated) and transferred to a processing device for subsequent processing operations.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. An apparatus for processing a substrate, the apparatus comprising:
a cup providing a processing space;
a support unit provided in the processing space, and for supporting a substrate;
a liquid supply unit including a nozzle for discharging a liquid to the substrate;
a position adjuster coupled to the nozzle and for adjusting a position of the nozzle; and
an adjustment unit coupled to the support unit, and for detecting pressure data when the liquid discharged from the nozzle meets the adjustment unit and position information at which the pressure data is generated.

2. The apparatus of claim 1, wherein the adjustment unit includes:
a base part seated on the support unit in place of the substrate;
a sensing part coupled to a top surface of the base part and including a plurality of pressure detecting elements that generates pressure data when receiving a pressure; and
a mapping part interworking with the sensing part and mapping position information to pressure data detected by each of the pressure detecting elements configuring the sensing part.

3. The apparatus of claim 2, wherein the base part is formed in a disk shape similar to the substrate.

4. The apparatus of claim 2, wherein the sensing part is formed in a ring shape when viewed from above.

5. The apparatus of claim 4, wherein an outer diameter of the sensing part is formed with an outer diameter smaller than an outer diameter of the base part, and
the outer diameter of the sensing part is spaced apart from the outer diameter of the base part by a predetermined distance.

6. The apparatus of claim 2, wherein the mapping part calculates a data center value of the mapped pressure data.

7. The apparatus of claim 6, wherein the mapping part filters the pressure data so that only pressure data of a predetermined value or greater is mapped among the pressure data.

8. The apparatus of claim 7, wherein the position information of each of the filtered mapping data is arithmetically averaged and calculated as a data center value.

9. The apparatus of claim 2, wherein the adjustment unit further includes a display part which interworks with the mapping part to receive pressure data and position information matched with the pressure data, generates mapping data based on the pressure data and the position information input from the mapping part, and displays the input pressure data and position information as the mapping data.

10. The apparatus of claim 2, wherein the adjustment unit further includes a position control part which interworks with the position adjuster, and transmits a position adjustment signal to the position adjuster to adjust the position of the nozzle.

11. The apparatus of claim 1, wherein the nozzle includes a plurality of nozzles,
at least one of the plurality of nozzles is a nozzle for spraying a treatment solution to process the substrate, and at least another of the plurality of nozzles is a nozzle for spraying a cleaning liquid to clean the substrate, and
the adjustment unit detects the pressure data and the position information for the plurality of nozzles.

12. The apparatus of claim 1, further comprising:
a scattering preventing guide disposed in an upper space of the support unit, and formed with a nozzle insertion groove into which the nozzle is inserted and which is formed from a lateral surface toward the center.

13-19. (canceled)

20. An apparatus for processing a substrate, the apparatus comprising:
a cup providing a processing space;
a support unit provided in the processing space, and for supporting a substrate;
a liquid supply unit including a nozzle for discharging a liquid onto the substrate;
a position adjuster coupled to the nozzle and for adjusting a position of the nozzle; and
an adjustment unit seated on the support unit and for detecting pressure data generated when the liquid discharged from the nozzle contacts the adjustment unit and position information at which the pressure data is generated,
wherein the adjustment unit includes:
a base part seated on the support unit in place of the substrate and formed in a shape of a disk;
a sensing part coupled to an upper surface of the base part, and including a plurality of pressure detecting elements that generate pressure data when receiving a pressure, and formed in a ring shape, and having an outer diameter smaller than an outer diameter of the base part;
a mapping part interworking with the sensing part and mapping position information to the pressure data detected by each of the pressure detecting elements configuring the sensing part;
a display part which interworks with the mapping part to receive pressure data and position information matched with the pressure data, generates mapping data based on the pressure data and the position information input from the mapping part, and displays the input pressure data and the position information as the mapping data; and
a position control part which interworks with the position adjuster and transmits a position adjustment signal to the position adjuster to adjust the position of the nozzle.
